(19) United States
(12) Patent Application Publication
(10) Pub. No.: US 2011/0084391 A1
(43) Pub. Date: Apr. 14, 2011

(54) Reducing Device Mismatch by Adjusting Titanium Formation

(75) Inventors: Shyh-Wei Cheng, Zhudong Township (TW); Pin-Shyne Chin, Hsin-Chu (TW); Kuo-Chio Liu, Hsin-Chu (TW); Che-Jung Chu, Hsin-Chu (TW); Ming-Chang Hsieh, Jhudong Township (TW); Hung-Lin Chen, Pingtung City (TW); Tian Sheng Lin, Yangmei Township (TW)

(73) Assignee: Taiwan Semiconductor Manufacturing Company, Ltd., Hsin-Chu (TW)

(21) Appl. No.: 12/842,753

(22) Filed: Jul. 23, 2010

Related U.S. Application Data
(60) Provisional application No. 61/251,549, filed on Oct. 14, 2009.

(51) Int. Cl. H01L 23/532

(52) U.S. Cl. 257/751; 257/E23.157

(57) ABSTRACT

An integrated circuit structure includes a semiconductor substrate; a first titanium layer over the semiconductor substrate, wherein the first titanium layer has a first thickness less than 130 Å; a first titanium nitride layer over and contacting the first titanium layer; and an aluminum-containing layer over and contacting the first titanium nitride layer.

This application claims the benefit of U.S. Provisional Application No. 61/251,549 filed on Oct. 14, 2009, entitled “Reducing Device Mismatch by Adjusting Titanium Formation,” which application is hereby incorporated herein by reference.

### TECHNICAL FIELD

This disclosure relates generally to the formation of interconnect structures in integrated circuits, and more particularly, to the formation of Al—Cu and TiN/Ti stacks.

### BACKGROUND

High-voltage metal-oxide-semiconductor (HVMOS) devices are used in many electrical devices, such as input/output (I/O) circuits, CPU power supplies, power management systems, analog-to-digital (AC) converters, digital-to-analog (DC) converters, etc. There are a variety of forms of HVMOS devices.

It has been found that high-voltage devices, particularly HVMOS devices, suffer from device mismatch problems, which means that HVMOS devices on a same chip, although designed to be identical, actually perform differently, such as saturation currents, threshold voltages, and the like. The device mismatch problem is more severe for high-voltage devices than low-voltage devices. The device mismatch problem posts a significant challenge for analog applications. For example, when the HVMOS devices are used to control gray levels of liquid crystal displays (LCDs), since the existing LCDs may require up to 2¹⁰ gray levels, the HVMOS devices for controlling different pixels have to be highly matched with each other. Otherwise, the mismatch in the gray levels of different pixels will result in unexpected effects occurring to images.

Although various methods have been used to reduce the device mismatch, these methods have limited effects. For example, alloy processes were used to neutralize the dangling bonds in semiconductor substrates. The alloy processes may generally reduce the device mismatch. However, it has been found that the effect of the alloy processes is still not satisfactory. Particularly, in certain situations, the alloy processes may actually worsen the device mismatch, and the effects of the alloy processes sometimes depend on the specific circuit design and layout.

### SUMMARY

In accordance with one aspect of the embodiment, an integrated circuit structure includes a semiconductor substrate; a first titanium layer over the semiconductor substrate, wherein the first titanium layer has a first thickness less than 160 Å; a first titanium nitride layer over and contacting the first titanium layer; and an aluminum-containing layer over and contacting the first titanium nitride layer.

Other embodiments are also disclosed.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1 through 3 are cross-sectional views of intermediate stages in the manufacturing of a metal pad in accordance with an embodiment;

FIG. 4 illustrates a cross-sectional view of a sample wafer, on which an alloy process is performed; and

FIG. 5 illustrates hydrogen concentrations at different depths of the sample wafer after an alloy process is performed to the sample wafer.

### DETAILED DESCRIPTION OF ILLUSTRATIVE EMBODIMENTS

The making and using of the embodiments are discussed in detail below. It should be appreciated, however, that the embodiments provide many applicable inventive concepts that can be embodied in a wide variety of specific contexts. The specific embodiments discussed are merely illustrative, and do not limit the scope of the embodiments.

A novel metal feature including a TiN/Ti stack and the method of forming the same are presented. The variations of the embodiment are also discussed. Throughout the various views and illustrative embodiments, like reference numbers are used to designate like elements.

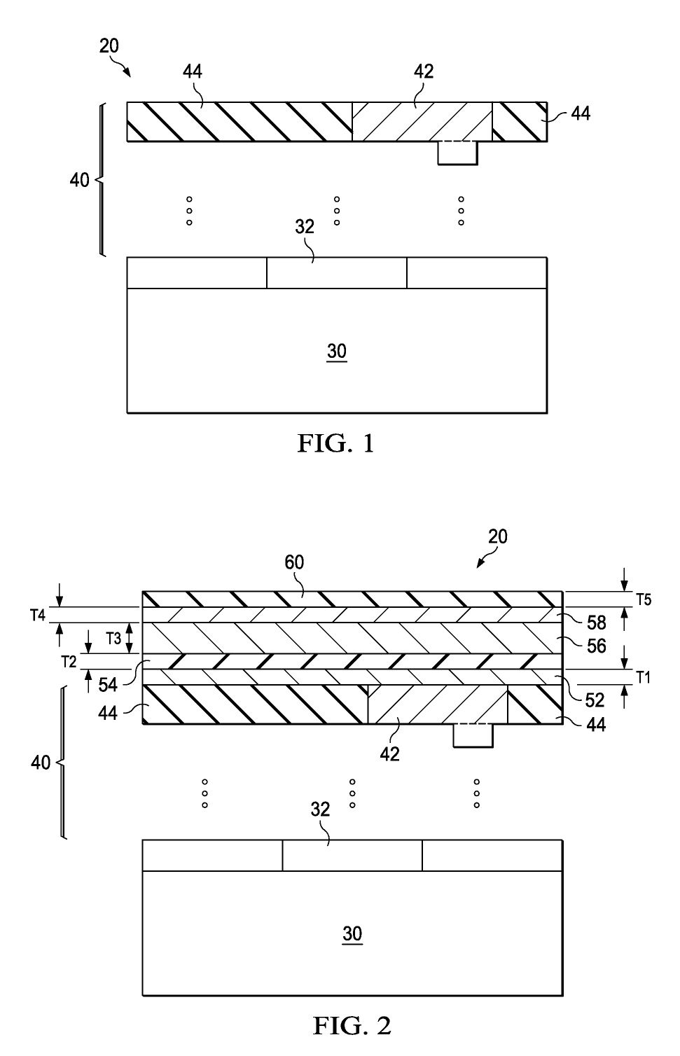

FIG. 1 illustrates a cross-sectional view of a portion of chip 20, which includes substrate 30, on which active circuit 32 is formed. Active circuit 32 may include high-voltage devices such as high-voltage PMOS (HVPMOS) devices and high-voltage NMOS (HVNMOS) devices, wherein the drain-to-gate voltages of the HVPMOS and HVNMOS devices may be higher than about 10 mV, or even higher than about 10V, for example. Substrate 30 may be a semiconductor substrate formed of commonly used semiconductor materials such as silicon, silicon germanium, or the like. Interconnect structure 40 is formed over active circuit 32, and is used to interconnect portions of active circuit 32, and to electrically connect active circuit 32 to metal pad 64 and/or redistribution line 62 (not shown in FIG. 1; refer to FIG. 3). Interconnect structure 40 includes a plurality of metallization layers comprising metal lines and vias (not shown) in a plurality of dielectric layers (not shown). The dielectric layers in interconnect structure 40 may be low-k dielectric layers. The metallization layers in interconnect structure 40 may include a top metallization layer Mtop, which includes top dielectric layer 44, and Mtop metal pad 42 in top dielectric layer 44. Mtop metal pad 42 may be formed of copper, and may have a single or dual damascene structure.

Next, a plurality of conductive layers is blanket formed. First, titanium (Ti) layer 52 is formed, for example, using physical vapor deposition (PVD). In an exemplary embodiment, Ti layer 52 is formed in a sputter tool including a first sputtering chamber (not shown), which may include a titanium target therein. In the formation of Ti layer 52, no nitrogen-containing gases such as N₂ are introduced into the sputtering chamber. Therefore, in an embodiment, Ti layer 52 may include substantially pure titanium, for example, with Ti atomic percentage greater than about 70% percent. It is realized, however, since Ti layer 52 may be formed in a same process chamber as titanium nitride (TiN) layers, there may be residue nitrogen that was left in the first sputtering chamber introduced into Ti layer 52. Further, the formation of overlying TiN layer 54 (FIG. 2) may cause nitrogen to diffuse into Ti layer 52. Accordingly, Ti layer 52 may sometimes be referred to as Ti-rich TiN layer 52. In this case, however, the Ti atomic percentage in Ti layer 52 is still greater than about 70% percent, and the nitrogen in Ti layer 52, if any, is less than about 10% percent.

Next, TiN layer 54 is formed. In an embodiment, TiN layer 54 may be formed in-situ with the formation of Ti layer 52, which means they are formed in the same sputtering chamber, and there is no vacuum break occurring between the formations of TiN layer 54 and Ti layer 52. At the time TiN layer 54 is formed, a nitrogen-containing process gas, such as N₂, is introduced into the process chamber, so that the sputtered Ti atoms form TiN with nitrogen. The Ti atomic percentage in TiN layer 54 may be lower than about 70% percent.

It is realized that due to the formation of TiN layer 54 and also due to the thermal budget in subsequent process steps, nitrogen may diffuse into Ti layer 52, causing the reduction in the thickness of Ti layer 52. In an embodiment, thickness T1 of the resulting Ti layer 52 is less than 130 Å, and possibly less than 100 Å or 75 Å, or even less than 50 Å. Thickness T2 of TiN layer 54 may be greater than about 70 Å, and possibly between about 90 Å and about 120 Å.

Next, aluminum (Al)-containing layer 56 is formed over, and possibly contacting, TiN layer 54. Al-containing layer 56 may be formed in a second sputtering chamber separate from the first sputtering chamber. Al-containing layer 56 may be formed of, or comprise, aluminum copper (Al—Cu) alloy, AlSiCu alloy, or the like. Thickness T3 of Al-containing layer 56 may be between about 3600 Å and about 9000 Å, although a greater or a smaller thickness may be used.

After the formation of Al-containing layer 56, Ti layer 58 is formed, followed by the formation of TiN layer 60. Ti layer 58 may be formed using essentially the same method, and have essentially the same composition, as Ti layer 52. TiN layer 60 may be formed using essentially the same method, and have essentially the same composition, as TiN layer 54. The formation details are thus not repeated herein.

In an embodiment, thickness T4 of Ti layer 58 is less than 170 Å, and possibly less than 130 Å, or even less than 50 Å. Thickness T5 of TiN layer 60 may be greater than about 700 Å, and possibly between about 750 Å and about 1500 Å. Further, thickness T1 of Ti layer 52 and thickness T4 of Ti layer 58 may have a total value of less than about 260 Å, or even less than about 200 Å or 150 Å.

Referring to FIG. 3, the stack including layers 52, 54, 56, 58, and 60 is patterned to form metal line 62 and metal pad 64. Metal line 62 may be used as a redistribution line, while metal pad 64 may be used to form under-bump-metallurgy (UBM) 66 thereon. Solder bump 68 may then be formed on UBM 66.

After the formation of metal line 62 and metal pad 64, an (hydrogen) alloy process may be performed. The alloy process may include annealing chip 20 in a hydrogen-containing environment, which may include H₂ gas. The alloy process may be performed, for example, at a temperature between about _{—}400° C. and about 460° C., for a duration between about 15 minutes and about 90 minutes. The alloy process has the effect of introducing hydrogen ions into semiconductor substrate 30, so that the hydrogen ions may act as the terminals of the dangling bonds in semiconductor substrate 30. The dangling bonds in semiconductor substrate 30 may originally exist in the respective wafer, or be generated in various integrated circuit formation processes such as etching, ashing, plasma processes, and the like. Therefore, by performing the alloy process, the dangling bonds are eliminated. The alloy process may result in the reduction in device mismatch. Particularly, in the case there are HVMOS devices in chip 20, since the impurity concentrations of doped regions in HVMOS devices are much lower than that of low-voltage MOS devices, the ratios of the concentrations of dangling bonds to the impurity concentrations are higher than that in low-voltage MOS devices. Dangling bonds thus affect the performance of HVMOS devices more than low-voltage MOS devices.

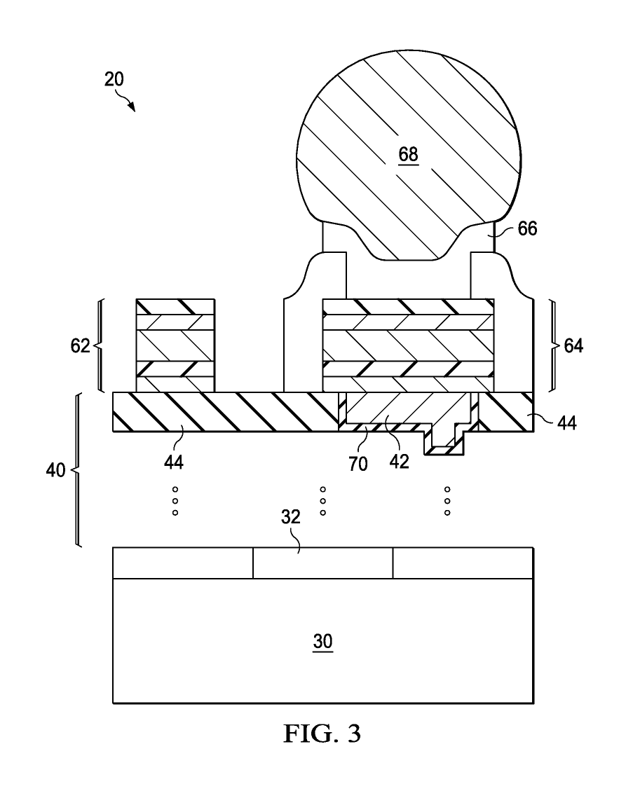

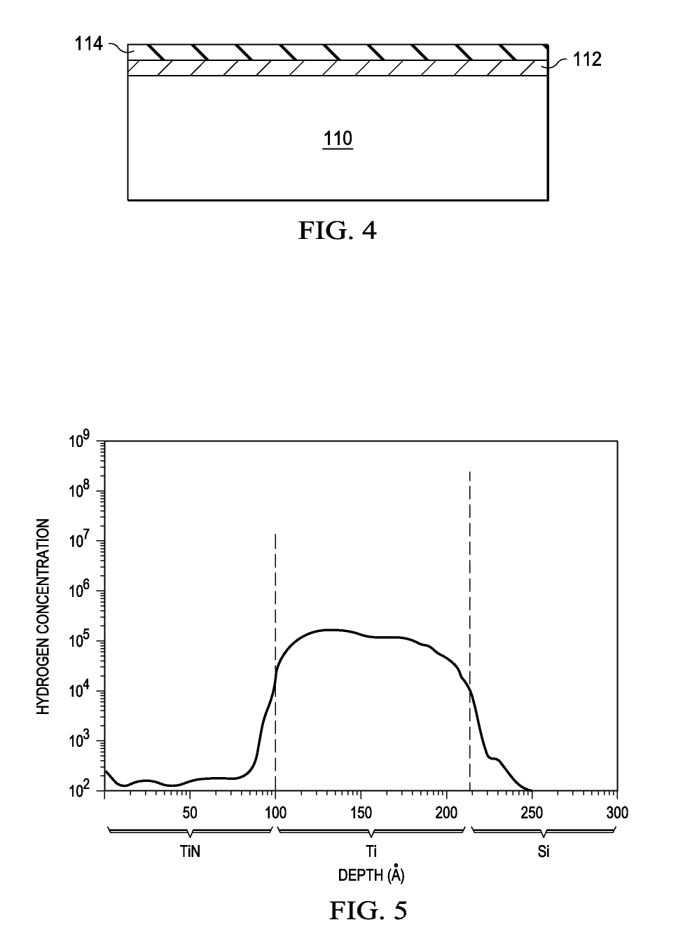

Experiments were performed to study the effect of the Ti thickness to the effect of alloy processes. FIG. 4 illustrates a sample wafer including silicon substrate 110, Ti layer 112, and TiN layer 114. An alloy process is performed to the sample wafer. The sample wafer is then analyzed using Secondary Ion Mass Spectrometry (SIMS). The result is shown in FIG. 5. The Y-axis indicates the hydrogen concentration, and the X-axis indicates the depth measured from the top of TiN layer 114 down into the sample wafer. Accordingly, TiN layer 114, Ti layer 112, and silicon substrate 110 are marked from left to right. It was found that the hydrogen concentration in Ti layer 112 is about three orders (1,000 times) higher than that in TiN layer 114 and silicon substrate 110. This means that Ti layer 112 traps a significant amount of hydrogen.

The experiment results shown in FIG. 5 indicate the unexpected result, that is, Ti layer 112 reduces the effect of alloy processes due to the fact that it blocks the hydrogen atoms/ions from penetrating through it to reach underlying substrate 110. Accordingly, in integrated circuits, the thicker the Ti layers are, the smaller the effect of the alloy process. Further, since Ti layers are patterned rather than uniformly distributed, where Ti layers do not exist, the alloy process has a better effect to the underlying silicon substrate, while where Ti layers exist, the alloy process has a worse effect to the underlying substrate. The devices at different locations of a substrate thus have different performances. Therefore, conventional Ti layers sometimes cause the alloy process to lose the function of reducing device mismatch, and sometimes may have the adverse effect of increasing the device mismatch.

The effect of the reduction in the thickness of Ti layers to the reduction of device mismatch is also revealed in further experiments. For example, referring back to FIG. 3, when thickness T1 of Ti layers 52 is 110 Å, the standard deviation of the threshold voltages of the PMOS devices on a chip was found to be 10.9 mV. When thickness T1 is increased to 120 Å, the standard deviation of the threshold voltages of the PMOS devices increases to 19.9 mV. However, when thickness T1 is reduced to 110 Å, the standard deviation of the threshold voltages of the PMOS devices decreases to 2.40 mV. These results indicate that the mismatch between devices may be reduced by reducing the thickness of Ti layers.

The embodiments, according to the above-discussed unexpected experiment results, have Ti layers with reduced thicknesses. Therefore, the adverse effect of Ti layers to alloy processes is reduced. To maximize the effect of the embodiments, the total thickness of Ti layers 52 and 58 that are directly overlying and underlying Al-containing layer 56 may be small. However, Ti layers 52 and 58 are not eliminated since they have the effect of reducing electro-migration. Further, in a same chip, any Ti layer, regardless of its position, may have a thickness less than 130 Å, or even less than 100 Å, or even less than 50 Å. In an exemplary embodiment, the diffusion barriers (for example, diffusion barrier layer 70 shown in FIG. 3) underlying copper damascene structures in metallization layers may include a TiN layer on a Ti layer, and the thickness of the Ti layer may be small, as discussed in preceding paragraphs.

The advantageous features of the embodiments include reduced device mismatch between high-voltage devices. The reduction in the device mismatch does not require additional process steps and/or additional design rules. Further, with the embodiments being adopted, extra alloy processes can be performed, if necessary, without the concern that the extra alloy processes will worsen the device mismatch.

Although the embodiments and their advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps. In addition, each claim constitutes a separate embodiment, and the combination of various claims and embodiments are within the scope of the invention.

What is claimed is:

1. An integrated circuit structure comprising:
a semiconductor substrate;
a first titanium layer over the semiconductor substrate, wherein the first titanium layer has a first thickness less than 130 Å;
a first titanium nitride layer over and contacting the first titanium layer; and
an aluminum-containing layer over and contacting the first titanium nitride layer.

2. The integrated circuit structure of claim 1, wherein the first thickness is less than 100 Å.

3. The integrated circuit structure of claim 2, wherein the first thickness is less than 50 Å.

4. The integrated circuit structure of claim 1, wherein the aluminum-containing layer further comprises copper.

5. The integrated circuit structure of claim 1, wherein the first titanium nitride layer has a thickness greater than about 700 Å.

6. The integrated circuit structure of claim 1 further comprising:
a second titanium layer over and contacting the aluminum-containing layer; and
a second titanium nitride layer over and contacting the second titanium layer, wherein all titanium layers in the integrated circuit structure and contacting the first titanium nitride layer and the second titanium nitride layer have a total thickness less than 200 Å.

7. The integrated circuit structure of claim 1, wherein the total thickness is less than 150 Å.

8. The integrated circuit structure of claim 1 further comprising a high-voltage MOS device at a surface of the semiconductor substrate, wherein a respective chip of the integrated circuit structure does not comprise any titanium layer with a thickness greater than 130 Å.

9. An integrated circuit structure comprising:
a semiconductor substrate;
a first titanium layer over the semiconductor substrate, wherein the first titanium layer has a first thickness less than 130 Å;
a first titanium nitride layer over and contacting the first titanium layer;
an aluminum copper (Al—Cu) layer over and contacting the first titanium nitride layer;
a second titanium layer over and contacting the Al—Cu layer; and
a second titanium nitride layer over and contacting the second titanium layer, wherein no additional titanium layer is over and contacting the second titanium nitride layer, and wherein the second titanium layer has a second thickness less than 130 Å.

10. The method of claim 9, wherein all titanium layers in the integrated circuit structure and contacting the first titanium nitride layer and the second titanium nitride layer have a total thickness less than 200 Å.

11. The method of claim 9, wherein both the first thickness and the second thickness are less than 100 Å.

12. The method of claim 9, wherein both the first thickness and the second thickness are less than 50 Å.

13. The method of claim 9 further comprising a high-voltage MOS device at a surface of the semiconductor substrate, wherein a respective chip of the integrated circuit structure does not comprise any titanium layer with a thickness greater than 130 Å.
